(19) United States
(12) Patent Application Publication
(10) Pub. No.: US 2019/0233726 A1
(43) Pub. Date: Aug. 1, 2019

(54) RED PHOSPHOR AND PRODUCTION METHOD THEREFOR, AND WHITE LIGHT SOURCE, ILLUMINATION DEVICE, AND DISPLAY DEVICE USING SAME

(71) Applicant: DEXERIALS CORPORATION, Tokyo (JP)

(72) Inventors: Moriaki ABE, Utsunomiya-shi (JP); Masaki KANNO, Tokyo (JP)

(73) Assignee: Dexerials Corporation, Tokyo (JP)

(21) Appl. No.: 16/319,921

(22) PCT Filed: Jul. 21, 2017
(86) PCT No.: PCT/JP2017/026583

§ 371 Date: Jan. 23, 2019

(30) Foreign Application Priority Data
Jul. 26, 2016 (JP) 2016-146477
Oct. 7, 2016 (JP) 2016-199406

(51) Int. Cl. C09K 11/77; F21K 9/64; H01L 33/50; H01L 27/15

(52) U.S. Cl. CPC C09K 11/7734; F21K 9/64; F21Y 2115/10; H01L 27/156; H01L 33/502

(57) ABSTRACT

Provided are a red phosphor having increased reflectivity in a green color gamut and a production method therefor, and a white light source, an illumination device, and a display device using the same. A red phosphor comprises a composition containing an alkaline earth metal element (A), europium (Eu), silicon (Si), aluminum (Al), oxygen (O), and nitrogen (N) at atomic ratios in the following Formula (1), and further containing carbon (C),

[A₍ₘ₋ₓ₎Euₓ]Si₉Al_{y}OₙN_{{12+y-2(n-m)/3}} (1)

where m, n, x, and y respectively satisfy 3<m<5, 0<n<10, 0<x<1, and 0<y<2, wherein the alkaline earth metal element (A) includes at least barium (Ba).

### CROSS REFERENCE TO RELATED APPLICATION

This application claims priority to and the benefit of Japanese Patent Application No. 2016-146477 filed on Jul. 26, 2016 and Japanese Patent Application No. 2016-199406 filed on Oct. 7, 2016, the entire disclosures of which are incorporated herein by reference.

### TECHNICAL FIELD

The present disclosure relates to a red phosphor and a production method therefor, and a white light source, an illumination device, and a display device using the same.

### BACKGROUND

For backlights of illumination devices and liquid crystal display devices, white light sources using light emitting diodes have conventionally been used. A widely used type of such white light sources is one in which a cerium-containing yttrium aluminum garnet (hereafter referred to as “YAG:Ce”) yellow phosphor is disposed on the emission surface side of a blue light emitting diode.

However, because the white light source including the YAG:Ce yellow phosphor disposed on the emission surface side of the blue light emitting diode lacks a red component in the emission spectrum of the YAG:Ce phosphor, white light appears bluish, and the color gamut is narrow. Thus, with an illumination device using such a white light source, it is difficult to produce pure white light and achieve illumination with excellent color rendering.

Hence, in recent years, a technique of producing light closer to natural light by using a red phosphor whose emission wavelength is on the long-wavelength side together with a green phosphor or a yellow phosphor has been put to actual use, and white light sources with improved color rendering has been developed actively.

For improvement in color rendering of white light, the intensity of red light emitted from the red phosphor is important. For example, JP 2011-001530 A (PTL 1) proposes an oxynitride-based red phosphor using a group II element. JP 2012-178580 A (PTL 2) proposes a white light source using an oxynitride-based red phosphor containing an alkaline earth metal element, europium, silicon, aluminum, oxygen, nitrogen, and carbon.

### CITATION LIST

### Patent Literatures

PTL 1: JP 2011-001530 A

PTL 2: JP 2012-178580 A

### SUMMARY

### Technical Problem

The oxynitride-based red phosphor described in PTL 1 can emit red light of higher emission intensity than conventional red phosphors. However, the red phosphor described in PTL 1 still has room for improvement in color rendering. We conducted intensive study on means for improving color rendering of white light obtained using a red phosphor together with a green phosphor or a yellow phosphor with a blue light emitting diode as an excitation light source.

FIG. 1 is a graph schematically illustrating commonly known luminosity factor characteristics. Even with light of the same emission intensity, if the wavelength is different, the brightness perceived by humans with the naked eye differs greatly. As illustrated in FIG. 1, the human eye is most sensitive to light in the green color gamut (approximately a wavelength range of 495 nm to 580 nm) of visible light, in particular light of a wavelength of 555 nm. Therefore, a slight difference in emission intensity at a wavelength of 555 nm influences color rendering significantly.

If the red phosphor absorbs light of wavelengths in the green color gamut, the light intensity of wavelengths in the green color gamut emitted from the green phosphor or the yellow phosphor used together with the red phosphor decreases. This makes it difficult to achieve desired brightness and high color rendering. We accordingly focused attention on the reflectivity of the red phosphor for light in the green color gamut, in particular light of a wavelength of 555 nm. The absorption of light in the green color gamut by the red phosphor can be prevented if the red phosphor has high reflectivity in the green color gamut. Such a red phosphor can be used to produce white light with excellent color rendering.

It could therefore be helpful to provide a red phosphor having increased reflectivity in the green color gamut. It could also be helpful to provide a production method for such a red phosphor, and a white light source, an illumination device, and a display device using the same.

### Solution to Problem

Through intensive study, we conceived the use of barium (Ba) as a constituent element of a red phosphor. We discovered that this makes it possible to obtain a red phosphor having increased reflectivity in the green color gamut.

The present disclosure is based on these discoveries. We thus provide:

<1> A red phosphor comprising

a composition containing an alkaline earth metal element (A), europium (Eu), silicon (Si), aluminum (Al), oxygen (O), and nitrogen (N) at atomic ratios in the following Formula (1), and further containing carbon (C),

[A₍ₘ₋ₓ₎Euₓ]Si₉Al_{y}OₙN_{{12+y-2(n-m)/3}} (1)

where m, n, x, and y respectively satisfy 3<m<5, O<n<10, 0<x<1, and 0<y<2,

wherein the alkaline earth metal element (A) includes at least barium (Ba).

The red phosphor according to <1> has increased reflectivity in the green color gamut.

<2> The red phosphor according to <1>, wherein a compositional formula of the red phosphor is expressed by the following Formula (2)

[A₍ₘ₋ₓ₎Euₓ]Si₉Al_{y}OₙN_{{12+y-2(n-m)/3}}:C (2)

where m, n, x, and y respectively satisfy 3<m<5, 0<n<10, 0<x<1, and 0<y<2.

<3> The red phosphor according to <1> or <2>, wherein in the Formula (1), a ratio of an amount of substance of the europium (Eu) to a total amount of substance of the europium (Eu) and the alkaline earth metal element (A) is 0.06 or more and 0.09 or less.

<4> The red phosphor according to any of <1> to <3>, wherein in the Formula (1), the alkaline earth metal element (A) includes at least calcium (Ca) and strontium (Sr), and

a ratio of an amount of substance of the barium (Ba) to a total amount of substance of the calcium (Ca), the strontium (Sr), and the barium (Ba) is 0.75 or more.

<5> The phosphor according to any of <1> to <4>, wherein a reflectivity at a wavelength of 555 nm is 38% or more.

<6> The phosphor according to any of <1> to <5>, wherein a reflectivity at a wavelength of 580 nm is 58% or more.

<7> A production method for a red phosphor, the production method comprising:

a mixing step of mixing a compound of an alkaline earth metal element (A), europium nitride, silicon nitride, aluminum nitride, and melamine to obtain a mixture;

a first burning step of burning the mixture to obtain a burned product;

a pulverization step of pulverizing the burned product to obtain a burned product powder; and

a second burning step of burning the burned product powder,

wherein the alkaline earth metal element (A) includes at least barium (Ba), and

the red phosphor has a composition containing the alkaline earth metal element (A), europium (Eu), silicon (Si), aluminum (Al), oxygen (O), and nitrogen (N) at atomic ratios in the foregoing Formula (1) and further containing carbon (C).

The phosphor production method according to <7> can produce a red phosphor having increased reflectivity in the green color gamut.

<8> The production method for a red phosphor according to <7>, wherein a compositional formula of the red phosphor is expressed by the foregoing Formula (2).

<9> A white light source comprising:

a blue light emitting diode located on an element substrate; and

a kneaded product located on the blue light emitting diode and obtained by kneading a green phosphor or a yellow phosphor and the red phosphor according to any of <1> to <6> with a transparent resin.

The white light source according to <9> can achieve high color rendering.

<10> An illumination device comprising

a plurality of white light sources arranged on a substrate,

wherein each of the plurality of white light sources includes:

a blue light emitting diode located on an element substrate; and

a kneaded product located on the blue light emitting diode and obtained by kneading a green phosphor or a yellow phosphor and the red phosphor according to any of <1> to <6> with a transparent resin.

The illumination device according to <10> can achieve high color rendering.

<11> A display device comprising:

a display panel; and

an illumination device that illuminates the display panel,

wherein the illumination device includes a plurality of white light sources arranged on a substrate, and

each of the plurality of white light sources includes:

a blue light emitting diode located on an element substrate; and

a kneaded product located on the blue light emitting diode and obtained by kneading a green phosphor or a yellow phosphor and the red phosphor according to any of <1> to <6> with a transparent resin.

The display device according to <11> can achieve high color rendering.

### Advantageous Effect

According to the present disclosure, the conventional problems can be solved and the object stated above can be achieved. It is thus possible to provide a red phosphor having increased reflectivity in the green color gamut and a production method therefor, and a white light source, an illumination device, and a display device using the same.

### BRIEF DESCRIPTION OF THE DRAWINGS

In the accompanying drawings:

FIG. 1 is a graph schematically illustrating commonly known luminosity factor characteristics;

FIG. 2 is a schematic diagram of a white light source using a red phosphor according to one of the disclosed embodiments;

FIG. 3 is a schematic diagram of an illumination device using a red phosphor according to one of the disclosed embodiments;

FIG. 4 is a schematic diagram of a display device using a red phosphor according to one of the disclosed embodiments;

FIG. 5 is a graph illustrating the reflectance spectrum of a phosphor in each example; and

FIG. 6 is a graph illustrating the emission spectrum of a phosphor in each example.

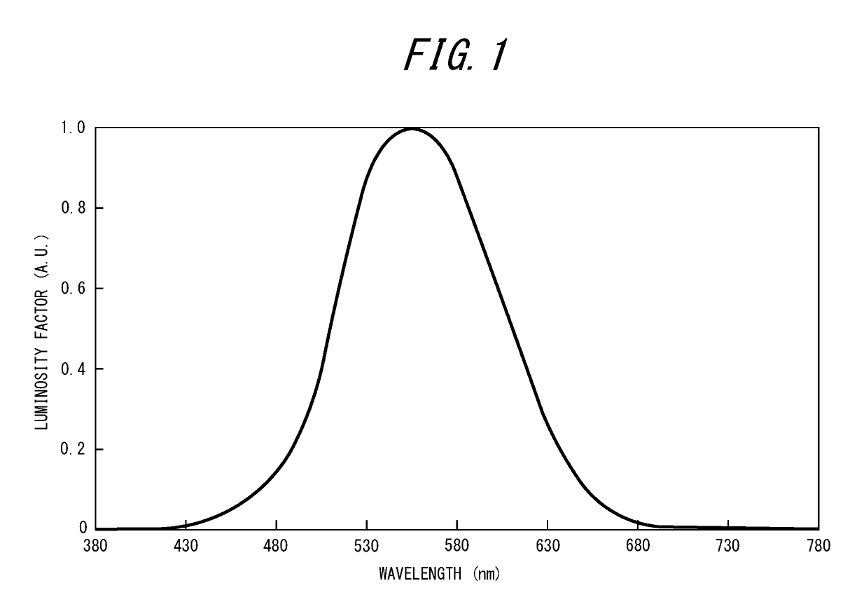

### DETAILED DESCRIPTION

(Red Phosphor)

A red phosphor according to one of the disclosed embodiments contains an alkaline earth metal element (A), europium (Eu), silicon (Si), aluminum (Al), carbon (C), oxygen (O), and nitrogen (N) as constituent elements. The red phosphor contains, of these constituent elements, the alkaline earth metal element (A), europium (Eu), silicon (Si), aluminum (Al), oxygen (O), and nitrogen (N) at the atomic ratios in the following Formula (1).

[A₍ₘ₋ₓ₎Euₓ]Si₉Al_{y}OₙN_{{12+y-2(n-m)/3}} (1)

(where m, n, x, and y respectively satisfy 3<m<5, 0<n<10, 0<x<1, and 0<y<2.)

The phosphor represented by Formula (1) has a crystal structure belonging to an orthorhombic space point group Pₘₙ₂₁. In such a crystal structure, aluminum (Al) substitutes for part of silicon (Si), and europium (Eu) which is an activating element substitutes for part of the alkaline earth metal element (A). The atomic ratio [12+y−2(n−m)/3] of nitrogen (N) in Formula (1) is calculated so that the sum of the atomic ratios of the respective elements in Formula (1) is neutral. In detail, when the atomic ratio of nitrogen (N) in Formula (1) is denoted by a and it is assumed that the charges of the elements in Formula (1) are compensated, the following formula holds true:

2(m−x)+2x+4×9+3y−2n−3α=0.

Hence, the atomic ratio α of nitrogen (N) is calculated at [12+y−2(n−m)/3]. In Formula (1), m, n, x, and y are not limited as long as the foregoing ranges are satisfied. The red phosphor according to this embodiment may contain other elements inevitably mixed in during production, as long as the red phosphor has the crystal structure described above.

Carbon (C) substitutes for part of silicon (Si), as with aluminum (Al). However, all carbon (C) does not necessarily substitute for part of silicon (Si), and part of carbon (C) may enter between the interstices of the phosphor to dissolve thereinto. Accordingly, the compositional formula of the red phosphor according to one of the disclosed embodiments can be expressed by the following Formula (2) instead of the foregoing Formula (1).

[A₍ₘ₋ₓ₎Euₓ]Si₉Al_{y}OₙN_{{12+y-2(n-m)/3}}:C (2)

(where m, n, x, and y respectively satisfy 3<m<5, 0<n<10, 0<x<1, and 0<y<2.)

The atomic ratio [12+y−2(n−m)/3] of nitrogen (N) in Formula (2) is calculated so that the sum of the atomic ratios of the respective elements in Formula (2) is neutral, as in Formula (1).

In the case where carbon (C) all substitutes for silicon (Si), the compositional formula of the red phosphor according to one of the disclosed embodiments can be expressed by the following Formula (3) instead of the foregoing Formula (2).

[A₍ₘ₋ₓ₎Euₓ][Si_{(9-z)}C_{z}]Al_{y}OₙN_{{12+y-2(n-m)/3}} (3)

(where m, n, x, y, and z respectively satisfy 3<m<5, 0<n<10, 0<x<1, 0<y<2, and <z<9.)

The atomic ratio [12+y−2(n−m)/3] of nitrogen (N) in Formula (3) is calculated so that the sum of the atomic ratios of the respective elements in Formula (3) is neutral, as in Formula (1).

In the red phosphor according to this embodiment, the alkaline earth metal element (A) includes at least barium (Ba). We experimentally determined that the inclusion of barium (Ba) in the alkaline earth metal element (A) in the red phosphor represented by Formula (1) can increase the reflectivity in the green color gamut, as compared with red phosphors not containing barium (Ba). Improvement in reflectivity especially at a wavelength of 555 nm has much greater effect on luminosity factor than other wavelength ranges, as mentioned earlier. Thus, the red phosphor according to this embodiment can be used to produce white light with excellent color rendering.

<Alkaline Earth Metal Element (A)>

The alkaline earth metal element (A) in this embodiment includes at least barium (Ba), as described above. The alkaline earth metal element (A) may include, in addition to barium (Ba), calcium (Ca), strontium (Sr), and radium (Ra). To obtain desired emission characteristics, in addition to barium (Ba), the alkaline earth metal element (A) preferably includes one or more of calcium (Ca), strontium (Sr), and radium (Ra), and more preferably includes one or both of calcium (Ca) and strontium (Sr). As the alkaline earth metal element (A), only three elements, namely, barium (Ba), calcium (Ca), and strontium (Sr), may be used.

In the case where the alkaline earth metal element (A) includes at least calcium (Ca) and strontium (Sr) in addition to barium (Ba), the ratio (molar ratio) of the amount of substance of barium (Ba) to the total amount of substance of calcium (Ca), strontium (Sr), and barium (Ba) is preferably 0.75 or more. In detail, when the amount of substance of calcium (Ca) is denoted by n_{Ca}, the amount of substance of strontium (Sr) is denoted by n_{Sr}, the amount of substance of barium (Ba) is denoted by n_{Ba}, and the molar ratio X_{Ba} of barium (Ba) in the alkaline earth metal element (A) is represented by the following Formula (4), X_{Ba} is preferably 0.75 or more. The same applies to the case where the alkaline earth metal element (A) includes only three elements: barium (Ba), calcium (Ca), and strontium (Sr).

$${X}_{Ba} = \frac{{n}_{Ba}}{{n}_{Ca} + {n}_{Sr} + {n}_{Ba}} \qquad ( 4 )$$

We experimentally determined that the reflectivity in the green color gamut of the red phosphor according to this embodiment can be increased more reliably in the case where X_{Ba} is 0.75 or more. No upper limit is placed on X_{Ba}, yet X_{Ba} is preferably 0.95 or less, and more preferably 0.90. The reflectivity in the green color gamut can be increased more reliably in this way. To ensure the advantageous effects according to the present disclosure, X_{B}a is preferably 0.80 or more.

In the case where the alkaline earth metal element (A) includes calcium (Ca), to further ensure the advantageous effects according to the present disclosure, when the molar ratio X_{Ca} of calcium (Ca) in the alkaline earth metal element (A) is represented by the following Formula (5), X_{Ca} is preferably 0.01 or more and 0.2 or less, and more preferably 0.02 or more and 0.15 or less. X_{Ca} is preferably 0.1 or more and 0.13 or less.

$${X}_{Ca} = \frac{{n}_{Ca}}{{n}_{Ca} + {n}_{Sr} + {n}_{Ba}} \qquad ( 5 )$$

In the case where the alkaline earth metal element (A) includes strontium (Sr), to further ensure the advantageous effects according to the present disclosure, when the molar ratio X_{Sr} of strontium (Sr) in the alkaline earth metal element (A) is represented by the following Formula (6), X_{Sr} is preferably 0.01 or more and 0.3 or less, and more preferably 0.1 or more and 0.27 or less. X_{Sr} is preferably 0.1 or more and 0.15 or less.

$${X}_{Sr} = \frac{{n}_{Sr}}{{n}_{Ca} + {n}_{Sr} + {n}_{Ba}} \qquad ( 6 )$$

<Europium (Eu)>

In the red phosphor according to this embodiment, europium (Eu) which is an activating element is not limited as long as 0<x<1 in the foregoing Formula (1), but more preferably satisfies the following relational formula. In other words, as the relationship in the amount of substance with the alkaline earth metal element (A) to be substituted by europium (Eu), the ratio of the amount of substance of europium (Eu) to the total amount of substance of europium (Eu) and the alkaline earth metal element (A) is preferably 0.06 or more and 0.09 or less. In detail, when the amount of substance of europium (Eu) is denoted by n_{Eu} and the molar ratio X_{Eu} of europium (Eu) to the total amount of substance of europium (Eu) and the alkaline earth metal element (A) is represented by the following Formula (7), X_{Eu} is preferably 0.06 or more and 0.09 or less. X_{Eu} may be 0.07 or more and 0.09 or less.

$${X}_{Eu} = \frac{{n}_{Eu}}{{n}_{Ca} + {n}_{Sr} + {n}_{Ba} + {n}_{Eu}} \qquad ( 7 )$$

The reflectivity at a wavelength of 555 nm of the red phosphor according to this embodiment may be 38% or more, may be 40% or more, and may be 44% or more. The reflectivity at a wavelength of 550 nm of the red phosphor according to this embodiment may be 35% or more, may be 37% or more, and may be 41% or more. The reflectivity at a wavelength of 580 nm of the red phosphor according to this embodiment may be 58% or more, may be 60% or more, and may be 63% or more.

<Carbon (C)>

In the red phosphor according to this embodiment, the content of carbon (C) is not limited, and may be 0.01 mol % or more and 0.50 mol % or less in molar ratio to the whole red phosphor. The content of carbon (C) is preferably 0.05 mol % or more, and more preferably 0.10 mol % or more. The content of carbon (C) is preferably 0.40 mol % or less, and more preferably 0.20 mol % or less.

(Production Method for Red Phosphor)

A production method for a red phosphor according to the present disclosure includes at least a mixing step, a first burning step, a pulverization step, and a second burning step, and optionally includes other steps selected as appropriate.

In detail, a production method for a red phosphor according to one of the disclosed embodiments includes: a mixing step of mixing a compound of the alkaline earth metal element (A), europium nitride, silicon nitride, aluminum nitride, and melamine to obtain a mixture; a first burning step of burning the mixture to obtain a burned product; a pulverization step of pulverizing the burned product to obtain a burned product powder; and a second burning step of burning the burned product powder. These steps yield a red phosphor in which the alkaline earth metal element (A) includes at least barium (Ba) and that has a composition containing the alkaline earth metal element (A), europium (Eu), silicon (Si), aluminum (Al), oxygen (O), and nitrogen (N) at the atomic ratios in the foregoing Formula (1) and further containing carbon (C).

In this embodiment, the mixing step is performed first. In the mixing step, melamine (C₃H₆N₆) is used as a carbon source and a nitrogen source in addition to a compound of the alkaline earth metal element (A), europium nitride, silicon nitride, and aluminum nitride, as raw material compounds including the elements in Formula (1).

Examples of a raw material compound as the compound of the alkaline earth metal element (A) include carbonate compounds, hydroxides, nitrides, and oxides of the alkaline earth metal element. Examples of a raw material compound of barium (Ba) include barium carbonate (BaCO₃), barium hydroxide (Ba(OH)₂), barium nitride (Ba₂N₃), and barium oxide (BaO).

Examples of a raw material compound of calcium (Ca) include calcium carbonate (CaCO₃), calcium hydroxide (Ca(OH)₂), calcium nitride (Ca₂N₃), and calcium oxide (CaO). Examples of a raw material compound of strontium include strontium carbonate (SrCO₃), strontium hydroxide (Sr(OH)₂), strontium nitride (Sr₂N₃), and strontium oxide (SrO).

The prepared raw material compounds are weighed at predetermined molar ratios so that the elements in Formula (1) included in the raw material compounds have the atomic ratios in Formula (1) after burning. The weighed compounds are then mixed to produce a mixture. For example, the mixture is produced in an agate mortar inside a glove box in a nitrogen atmosphere.

Note that melamine is a flux. Thus, melamine should be added in a predetermined proportion to the total number of moles of the raw material compounds other than melamine.

The first burning step is then performed. In the first burning step, the mixture obtained as a result of the mixing step is burned to produce a first burned product which is a red phosphor precursor. For example, the mixture may be put in a crucible made of boron nitride, and heat-treated in a hydrogen (H₂) and/or nitrogen (N₂) atmosphere. In the first burning step, for example, the heat treatment temperature is 1200° C. or more and 1600° C. or less, and the heat treatment time is 1 hr or more and 6 hr or less.

In the first burning step, melamine having a melting point of 250° C. or less is thermally decomposed. Carbon (C) and hydrogen (H) resulting from this thermal decomposition combine with part of oxygen (O) and the like contained in each raw material compound. For example, in the case where carbon (C) and hydrogen (H) combine with oxygen (O) of carbonate, carbonic acid gas (CO or CO₂), H₂O, and the like are produced, and such carbonic acid gas and H₂O evaporate. Moreover, nitrogen (N) contained in the decomposed melamine promotes reduction and nitriding.

After the first burning step, the pulverization step is performed. In the pulverization step, the burned product is pulverized to obtain a burned product powder. For example, the burned product is pulverized using an agate mortar inside a glove box in a nitrogen atmosphere, and then passed through, for example, a #100 mesh (having an opening of approximately 200 μm), to obtain a burned product powder having an average particle diameter of approximately 5 μm or less.

The second burning step is then performed. In the second burning step, the burned product powder is heat-treated to obtain the red phosphor according to this embodiment. For example, the burned product powder is put in a crucible made of boron nitride, and heat-treated in a nitrogen (N₂) and/or hydrogen (H₂) atmosphere. In the second burning step, for example, the atmosphere is pressurized to 0.5 MPa or more and 1.1 MPa or less, the heat treatment temperature is 1600° C. or more and 2000° C. or less, and the heat treatment time is 1 hr or more and 6 hr or less. Depending on the raw material compounds, the heat treatment temperature may be −30° C. to 0° C. in a reducing atmosphere of nitrogen (N₂) and hydrogen (H₂).

The resultant red phosphor may be further pulverized into a fine powder, according to need. The resultant fine powder (e.g. average particle diameter of several μm) of the red phosphor is, for example, kneaded with a transparent resin together with a powder of a green phosphor. Uniform kneading can thus be performed.

The production conditions described above are merely an example, and various changes are possible. The red phosphor described above can be yielded according to the embodiment of the production method described above. The red phosphor according to the present disclosure may be obtained by a production method other than the embodiment of the production method described above.

(White Light Source)

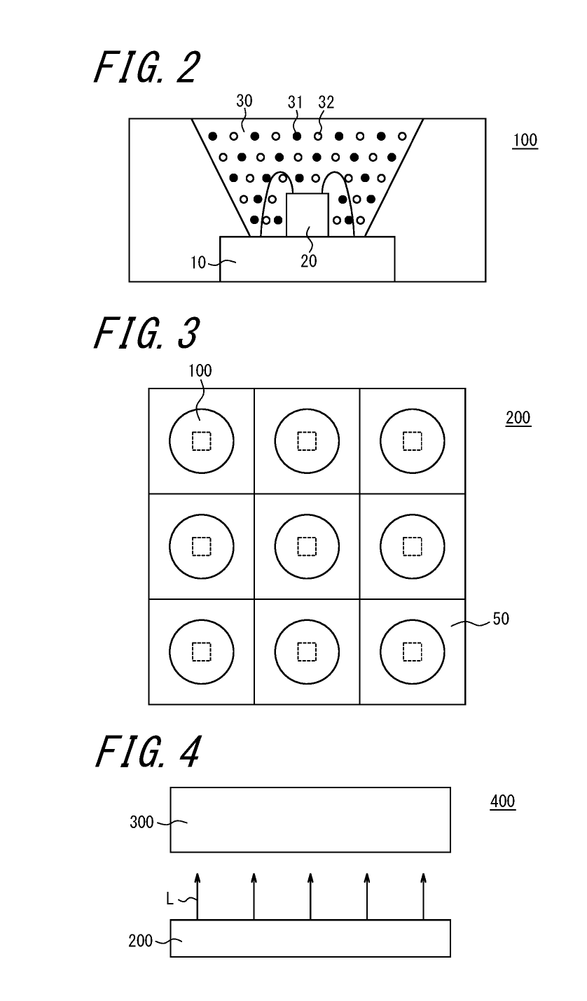

A white light source according to one of the disclosed embodiments will be described below, with reference to a schematic diagram in FIG. 2. A white light source 100 according to this embodiment includes a blue light emitting diode 20 located on an element substrate 10, and a kneaded product 30 located on the blue light emitting diode 20 and obtained by kneading a green phosphor 31 and a red phosphor 32 according to the present disclosure with a transparent resin. A yellow phosphor may be used instead of or in addition to the green phosphor 31.

The element substrate 10, the blue light emitting diode 20, the green phosphor 31, and the yellow phosphor may be a known substrate, light emitting diode, and phosphors. The white light source 100 may include other components such as a pad portion, electrodes, lead wires, and a reflective film, according to need.

The white light source 100 includes the red phosphor 32 according to the present disclosure, and thus can achieve high color rendering.

(Illumination Device)

An illumination device according to one of the disclosed embodiments will be described below, with reference to a schematic diagram in FIG. 3. An illumination device 200 according to this embodiment is an illumination device 200 in which a plurality of white light sources 100 are arranged on a substrate 50. Each white light source 100 includes the blue light emitting diode 20 located on the element substrate 10 and the kneaded product 30 located on the blue light emitting diode 20 and obtained by kneading the green phosphor 31 or a yellow phosphor and the red phosphor 32 according to the present disclosure with a transparent resin, as described above.

The substrate 50 may be a known substrate. The white light source 100 is as described above. The plurality of white light sources may be arranged in a square lattice as illustrated in FIG. 3, arranged regularly with different pitches, or arranged randomly. The illumination device 200 may include a control circuit not illustrated.

The illumination device 200 includes the red phosphor 32 according to the present disclosure, and thus can achieve high color rendering.

(Display Device)

A display device 400 according to one of the disclosed embodiments will be described below, with reference to a schematic diagram in FIG. 4. The display device 400 according to this embodiment includes a display panel 300 and an illumination device 200 that illuminates the display panel 300. The illumination device 200 includes the plurality of white light sources 100 arranged on the substrate 50. Each white light source 100 includes the blue light emitting diode 20 located on the element substrate 10, and the kneaded product 30 located on the blue light emitting diode 20 and obtained by kneading the green phosphor 31 or a yellow phosphor and the red phosphor 32 according to the present disclosure with a transparent resin. The display panel 300 may have a typical structure such as a liquid crystal panel. In the display device 400, light L emitted from the illumination device 200 is incident on the display panel 300, to enable image display. The white light source 100 is as described above.

The display device 400 includes the red phosphor 32 according to the present disclosure, and thus can achieve high color rendering.

### EXAMPLES

More detailed description will be given below by way of examples, although the present disclosure is not limited to these examples.

### Example 1

Barium carbonate (BaCO₃), calcium carbonate (CaCO₃), strontium carbonate (SrCO₃), europium nitride (EuN), silicon nitride (Si₃N₄), and aluminum nitride (AlN) were weighed at the molar ratios (mol %) shown in Table 1. Further, melamine (C₃H₆N₆) was weighed at 50 mol % with respect to the total number of moles of the foregoing compounds. These were mixed in an agate mortar inside a glove box in a nitrogen atmosphere, to obtain a mixture.

The mixture was then put in a crucible made of boron nitride, and heat-treated at 1550° C. for 2 hr in a hydrogen (H₂) atmosphere, to obtain a burned product. The burned product was then pulverized in a nitrogen atmosphere, to obtain a burned product powder. The burned product powder was further put in a crucible made of boron nitride, and heat-treated at 1800° C. for 2 hr in a nitrogen (N₂) atmosphere of 0.85 MPa, to obtain a red phosphor. Lastly, the red phosphor was pulverized and classified in a nitrogen atmosphere, to produce a red phosphor fine powder as a red phosphor according to Example 1.

### Conventional Example 1

A red phosphor according to Conventional Example 1 was produced in the same way as Example 1, except that barium carbonate (BaCO₃) was not used and weighing was performed at the molar ratios (mol %) shown in Table 1.

TABLE 1
unit: mol %

| | Ca | Sr | Ba | Eu | Si | Al |
|---|---|---|---|---|---|---|
| Example 1 | 3.1 | 3.1 | 24.9 | 2.2 | 66.0 | 0.7 |
| Conventional Example 1 | 9.4 | 21.8 | 0.0 | 2.2 | 65.7 | 1.0 |

### Examples 2 to 15

Red phosphors according to Examples 2 to 15 were produced in the same way as Example 1, except that the blending quantities of the raw materials of barium carbonate (BaCO₃), calcium carbonate (CaCO₃), strontium carbonate (SrCO₃), europium nitride (EuN), silicon nitride (Si₃N₄), aluminum nitride (AlN), and melamine (C₃H₆N₆) were changed from Example 1.

<Evaluation>

For the red phosphors according to Examples 1 to 15 and Conventional Example 1, A) component analysis, B) reflectivity, and C) emission characteristics were evaluated.

A) Component Analysis

For Examples 1 to 15 and Conventional Example 1, the constituent elements were subjected to mass analysis, and the atomic ratio (molar ratio) of each element was calculated. Regarding the component ratio of each of the metal elements calcium (Ca), strontium (Sr), barium (Ba), europium (Eu), silicon (Si), and aluminum (Al), mass analysis was performed by ICP emission spectrometry using a high-frequency inductively coupled plasma emission spectrometric analyzer (produced by Shimadzu Corporation, ICPS-8100). Regarding oxygen (O) and nitrogen (N), oxygen (O) was mass analyzed by inert gas transportation fusion infrared absorption method and nitrogen (N) was mass analyzed by inert gas transportation fusion conductivity method, using an oxygen nitrogen analyzer (produced by Leco Japan Corporation, ONH-836). Carbon (C) was mass analyzed by high-frequency heating furnace-type combustion infrared absorption method using a carbon sulfur analyzer (produced by Leco Japan Corporation, CS-844). The results are shown in Table 2.

In Table 2, X′_{Ca}, X′_{Sr}, X′_{Ba}, X′_{Eu}, RM_{Si}, and RM_{Al} are defined as follows. X′_{Ca}, X′_{Sr}, X′_{Ba}, and X′_{Eu} represent Formulas (4) to (7) in percentage, and RM_{Si} and RM_{Al} correspond to the atomic ratios (%) of the elements of Si and Al to all metal elements other than O, N, and C in the red phosphor. Here, Si is regarded as a metal element in the broad sense.

X′_{Ca}=100×n_{Ca}/(n_{Ba}+n_{Ca}+n_{Sr})

X′_{Sr}=100×n_{Sr}/(n_{Ba}+n_{Ca}+n_{Sr})

X′_{Ba}=100×n_{Ba}/(n_{Ba}+n_{Ca}+n_{Sr})

X′_{Eu}=100×n_{Eu}/(n_{Ba}+n_{Ca}+n_{Sr}+n_{Eu})

RM_{Si}=100×n_{Si}/(n_{Ba}+n_{Ca}+n_{Sr}+n_{Eu}+n_{Si}+n_{Al})

RM_{Al}=100×n_{Al}/(n_{Ba}+n_{Ca}+n_{Sr}+n_{Eu}+n_{Si}+n_{Al}).

TABLE 2

| | | | | | | | | | | | | | Central |
|---|---|---|---|---|---|---|---|---|---|---|---|---|---|
| | | | | | | | | | | | | | emission |
| | | | | | | | O | N | C | Reflectivity | Reflectivity | Reflectivity | wavelength |
| | X′_{Ca} | X′_{Sr} | X′_{Ba} | X′_{Eu} | RM_{Si} | RM_{Al} | [mol %] | [mol %] | [mol %] | (550 nm) | (555 nm) | (580 nm) | (nm) |
| Conventional | 31.2 | 68.8 | 0.0 | 3.9 | 70.8 | 1.00 | 0.98 | 49.0 | 0.45 | 32% | 35% | 55% | 651 |
| Example 1 | | | | | | | | | | | | | |
| Example 1 | 12.0 | 11.1 | 76.8 | 7.9 | 71.9 | 0.61 | 3.41 | 50.4 | 0.15 | 37% | 41% | 61% | 651 |
| Example 2 | 10.9 | 0.1 | 89.0 | 7.9 | 71.6 | 0.65 | 4.10 | 50.5 | 0.12 | 39% | 42% | 62% | 651 |
| Example 3 | 10.0 | 11.0 | 79.0 | 7.2 | 70.0 | 0.64 | 6.90 | 54.8 | 0.13 | 37% | 40% | 61% | 654 |
| Example 4 | 11.4 | 12.7 | 75.8 | 8.5 | 72.9 | 0.70 | 1.66 | 54.8 | 0.15 | 35% | 38% | 58% | 655 |
| Example 5 | 12.3 | 13.1 | 74.7 | 8.9 | 73.2 | 0.70 | 1.25 | 56.1 | 0.15 | 33% | 36% | 56% | 657 |
| Example 6 | 10.7 | 23.9 | 65.4 | 7.7 | 69.6 | 0.75 | 2.74 | 54.4 | 0.18 | 33% | 36% | 57% | 648 |
| Example 7 | 11.8 | 26.1 | 62.1 | 8.6 | 70.5 | 0.77 | 1.13 | 56.9 | 0.18 | 34% | 37% | 57% | 653 |
| Example 8 | 11.7 | 0.2 | 88.1 | 7.6 | 71.9 | 0.69 | 8.74 | 56.0 | 0.08 | 39% | 42% | 60% | 661 |
| Example 9 | 11.9 | 0.1 | 88.0 | 8.4 | 73.8 | 0.72 | 3.73 | 55.2 | 0.10 | 39% | 42% | 61% | 658 |
| Example 10 | 10.0 | 10.4 | 79.5 | 7.0 | 67.6 | 2.02 | 6.14 | 52.8 | 0.13 | 36% | 39% | 59% | 656 |
| Example 11 | 10.7 | 11.0 | 78.2 | 7.7 | 67.6 | 2.22 | 3.22 | 54.8 | 0.17 | 36% | 40% | 60% | 653 |
| Example 12 | 12.1 | 12.6 | 75.3 | 8.9 | 73.6 | 2.10 | 1.71 | 54.5 | 0.10 | 37% | 40% | 60% | 657 |
| Example 13 | 2.8 | 12.3 | 85.0 | 7.1 | 67.8 | 0.69 | 7.74 | 54.8 | 0.12 | 41% | 44% | 63% | 647 |
| Example 14 | 2.9 | 13.1 | 84.0 | 7.7 | 70.2 | 0.70 | 4.33 | 55.1 | 0.13 | 42% | 46% | 66% | 644 |
| Example 15 | 3.5 | 14.5 | 82.1 | 8.9 | 73.9 | 0.66 | 1.28 | 55.0 | 0.13 | 41% | 45% | 65% | 644 |

In Examples 2, 8, and 9, a minute amount of strontium was detected as shown in Table 2, despite not using strontium carbonate (SrCO₃) as the raw material compound of strontium. This is because other raw material compounds contained strontium as an impurity.

B) Reflectivity

The red phosphors according to Examples 1 to 15 and Conventional Example 1 were each spectroscopically evaluated to obtain a reflectance spectrum. A fluorescence spectrophotometer (produced by JASCO Corporation, FP-6000) equipped with an integrating sphere unit (produced by JASCO Corporation, ISF-513) was used in the spectroscopic evaluation. As measurement samples, the red phosphors according to Examples 1 to 15 and Conventional Example 1 were each placed in a powder measurement cell (produced by JASCO Corporation, PSH-002) of the fluorescence spectrophotometer. The window glass of the powder measurement cell was made of quartz, and measurement was performed by a reflection optical system through the glass. As a standard sample, a white plate (produced by Labsphere, Inc., Spectralon) made of a thermoplastic resin was used.

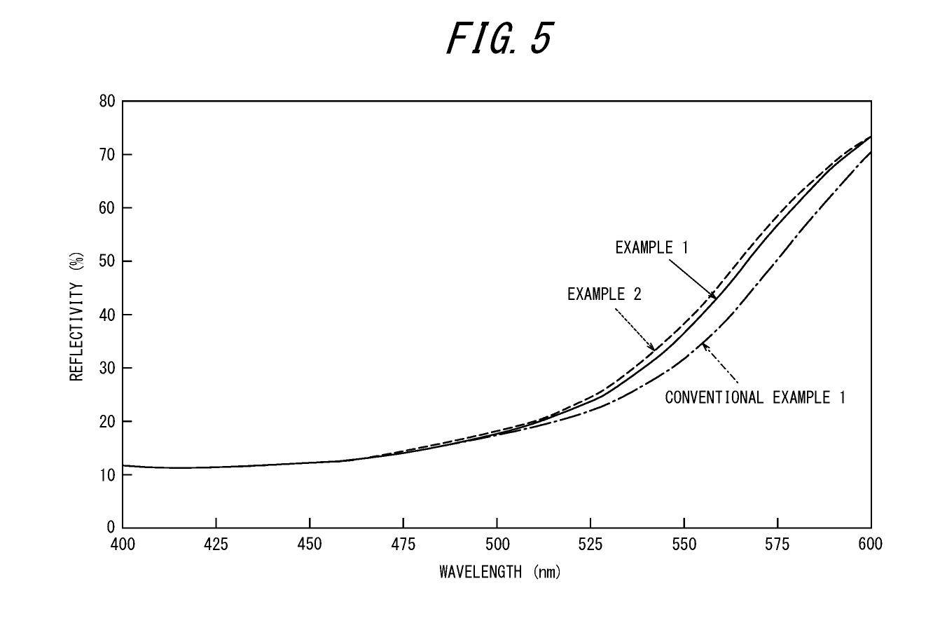

The wavelength of spectrally irradiated measurement light (excitation light) and the wavelength of spectrally measured reflected light were set to be the same. Wavelength scanning was performed with excitation-side bandpass: 5 nm, fluorescence-side bandpass: 5 nm, wavelength scanning: 200 nm/min, and response: 2 sec, to obtain the synchronization spectrum of the phosphor sample. The synchronization spectrum of the white plate as a sample was obtained in the same way. The synchronization spectrum of the phosphor sample was normalized by the synchronization spectrum of the white plate, thus obtaining the reflectance spectrum of the phosphor except fluorescence. The reflectance spectrum was thus obtained per 1 nm from 400 nm to 600 nm. FIG. 5 illustrates the reflectance spectrum of each of the red phosphors according to Examples 1 and 2 and Conventional Example 1 as representative examples. The reflectivity of each sample at 550 nm, 555 nm, and 580 nm is shown in Table 2.

C) Emission Characteristics

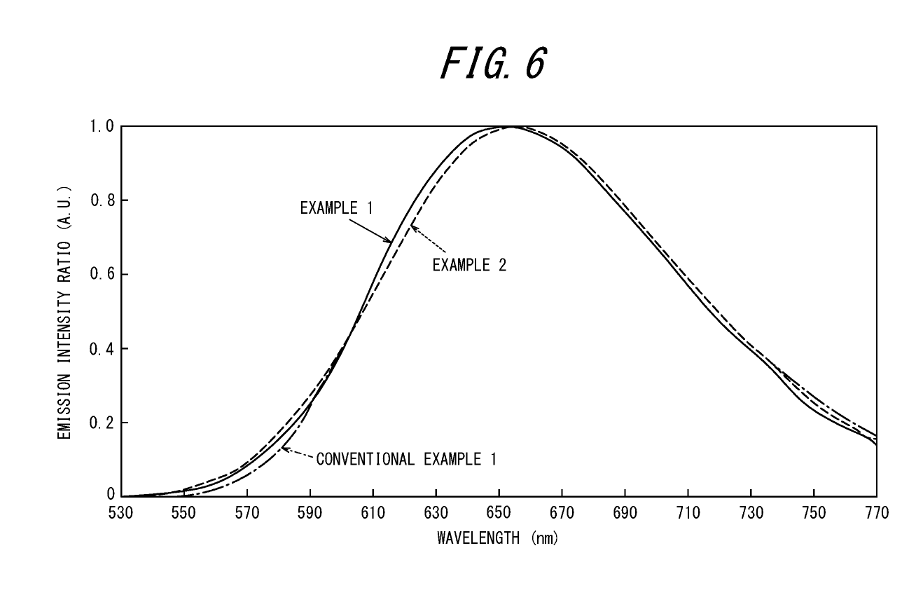

To evaluate the emission characteristics of the red phosphors according to Examples 1 to 15 and Conventional Example 1, the emission spectrum of each phosphor was measured per 1 nm from 530 nm to 770 nm using the above-mentioned fluorescence spectrophotometer. FIG. 6 illustrates the emission spectrum of each of the red phosphors according to Examples 1 and 2 and Conventional Example 1 as representative examples. The emission intensity ratio in FIG. 6 is normalized with the emission intensity at the emission peak wavelength of the red phosphor being 1. In all of Examples 1 to 15 and Conventional Example 1, the central emission wavelength was in a range of 644 nm to 661 nm (average: 652 nm). In the case where the same excitation light source was used for the emission intensity at the central emission wavelength of Conventional Example 1, the emission intensity at the central emission wavelength of each of Examples 1 to 15 was approximately the same, and had, if any, a decrease of at most about 5%.

These results demonstrate the following.

The red phosphors according to Examples 1 to 15 contained barium (Ba) as the alkaline earth metal element. Therefore, in Examples 1 to 15, the reflectivity increased at each of wavelengths of 550 nm, 555 nm, and 580 nm, as compared with Conventional Example 1 not containing barium (Ba). Particularly in the red phosphors according to Examples 1 to 4 and 8 to 15 in which the atomic ratio (molar ratio) of barium (Ba) to the alkaline earth metal element was more than 75%, the reflectivity at a wavelength of 550 nm was 35% or more, the reflectivity at a wavelength of 555 nm was 38% or more, and the reflectivity at a wavelength of 580 nm was 58% or more. Thus, the reflectivity increased markedly as compared with the reflectivity of Conventional Example 1. By providing the red phosphor according to any of Examples 1 to 15 in a mixture with a green phosphor (or a yellow phosphor) on the emission surface side of a blue light emitting diode, white light with excellent color rendering can be achieved.

### INDUSTRIAL APPLICABILITY

It is thus possible to provide a red phosphor having increased reflectivity in the green color gamut and a production method therefor, and a white light source, an illumination device, and a display device using the same.

### REFERENCE SIGNS LIST

10 element substrate
20 blue light emitting diode
30 kneaded product
31 green phosphor
32 red phosphor
50 substrate
100 white light source
200 illumination device
300 display panel
400 display device

1.-11. (canceled)

12. A red phosphor comprising
a composition containing an alkaline earth metal element (A), europium (Eu), silicon (Si), aluminum (Al), oxygen (O), and nitrogen (N) at atomic ratios in the following Formula (1), and further containing carbon (C),
[A₍ₘ₋ₓ₎Euₓ]Si₉Al_{y}OₙN_{{12+y-2(n-m)/3}} (1)
where m, n, x, and y respectively satisfy 3<m<5, 0<n<10, 0<x<1, and 0<y<2,
wherein the alkaline earth metal element (A) includes at least barium (Ba).

13. The red phosphor according to claim 12, wherein a compositional formula of the red phosphor is expressed by the following Formula (2)
[A₍ₘ₋ₓ₎Euₓ]Si₉Al_{y}OₙN_{{12+y-2(n-m)/3}}:C (2)
where m, n, x, and y respectively satisfy 3<m<5, 0<n<10, 0<x<1, and 0<y<2.

14. The red phosphor according to claim 12, wherein in the Formula (1), a ratio of an amount of substance of the europium (Eu) to a total amount of substance of the europium (Eu) and the alkaline earth metal element (A) is 0.06 or more and 0.09 or less.

15. The red phosphor according to claim 12, wherein in the Formula (1), the alkaline earth metal element (A) includes at least calcium (Ca) and strontium (Sr), and
a ratio of an amount of substance of the barium (Ba) to a total amount of substance of the calcium (Ca), the strontium (Sr), and the barium (Ba) is 0.75 or more.

16. The red phosphor according to claim 12, wherein a reflectivity at a wavelength of 555 nm is 38% or more.

17. The red phosphor according to claim 12, wherein a reflectivity at a wavelength of 580 nm is 58% or more.

18. The red phosphor according to claim 13, wherein in the Formula (1), a ratio of an amount of substance of the europium (Eu) to a total amount of substance of the europium (Eu) and the alkaline earth metal element (A) is 0.06 or more and 0.09 or less.

19. The red phosphor according to claim 13, wherein in the Formula (1), the alkaline earth metal element (A) includes at least calcium (Ca) and strontium (Sr), and
a ratio of an amount of substance of the barium (Ba) to a total amount of substance of the calcium (Ca), the strontium (Sr), and the barium (Ba) is 0.75 or more.

20. The red phosphor according to claim 13, wherein a reflectivity at a wavelength of 555 nm is 38% or more.

21. The red phosphor according to claim 13, wherein a reflectivity at a wavelength of 580 nm is 58% or more.

22. A production method for a red phosphor, the production method comprising:
a mixing step of mixing a compound of an alkaline earth metal element (A), europium nitride, silicon nitride, aluminum nitride, and melamine to obtain a mixture;
a first burning step of burning the mixture to obtain a burned product;
a pulverization step of pulverizing the burned product to obtain a burned product powder; and
a second burning step of burning the burned product powder,
wherein the alkaline earth metal element (A) includes at least barium (Ba), and
the red phosphor has a composition containing the alkaline earth metal element (A), europium (Eu), silicon (Si), aluminum (Al), oxygen (O), and nitrogen (N) at atomic ratios in the following Formula (1) and further containing carbon (C),
[A₍ₘ₋ₓ₎Euₓ]Si₉Al_{y}OₙN_{{12+y-2(n-m)/3}} (1)
where m, n, x, and y respectively satisfy 3<m<5, 0<n<10, 0<x<1, and 0<y<2.

23. The production method for a red phosphor according to claim 22, wherein a compositional formula of the red phosphor is expressed by the following Formula (2)
[A₍ₘ₋ₓ₎Euₓ]Si₉Al_{y}OₙN_{{12+y-2(n-m)/3}}:C (2)
where m, n, x, and y respectively satisfy 3<m<5, 0<n<10, 0<x<1, and 0<y<2.

24. A white light source comprising:
a blue light emitting diode located on an element substrate; and
a kneaded product located on the blue light emitting diode and obtained by kneading a green phosphor or a yellow phosphor and the red phosphor according to claim 12 with a transparent resin.

25. A white light source comprising:
a blue light emitting diode located on an element substrate; and
a kneaded product located on the blue light emitting diode and obtained by kneading a green phosphor or a yellow phosphor and the red phosphor according to claim 13 with a transparent resin.

26. An illumination device comprising
a plurality of white light sources arranged on a substrate,
wherein each of the plurality of white light sources includes:
a blue light emitting diode located on an element substrate; and
a kneaded product located on the blue light emitting diode and obtained by kneading a green phosphor or a yellow phosphor and the red phosphor according to claim 12 with a transparent resin.

27. An illumination device comprising
a plurality of white light sources arranged on a substrate,
wherein each of the plurality of white light sources includes:
a blue light emitting diode located on an element substrate; and
a kneaded product located on the blue light emitting diode and obtained by kneading a green phosphor or a yellow phosphor and the red phosphor according to claim 13 with a transparent resin.

28. A display device comprising:
a display panel; and
an illumination device that illuminates the display panel,
wherein the illumination device includes a plurality of white light sources arranged on a substrate, and
each of the plurality of white light sources includes:
a blue light emitting diode located on an element substrate; and
a kneaded product located on the blue light emitting diode and obtained by kneading a green phosphor or a yellow phosphor and the red phosphor according to claim 12 with a transparent resin.

29. A display device comprising:
a display panel; and
an illumination device that illuminates the display panel,
wherein the illumination device includes a plurality of white light sources arranged on a substrate, and
each of the plurality of white light sources includes:
a blue light emitting diode located on an element substrate; and
a kneaded product located on the blue light emitting diode and obtained by kneading a green phosphor or a yellow phosphor and the red phosphor according to claim 13 with a transparent resin.
